(19) United States
(12) Patent Application Publication
(10) Pub. No.: US 2022/0091281 A1
(43) Pub. Date: Mar. 24, 2022

(54) NEUTRON AND GAMMA MULTI-ELEMENT ALANINE DOSIMETER HOLDER

(71) Applicant: The United States of America as Represented by the Secretary of the Navy, Silver Spring, MD (US)

(72) Inventor: Alexander A. Romanyukha, Rockville, MD (US)

(73) Assignee: The United States of America as Represented by the Secretary of the Navy, Silver Spring, MD (US)

(21) Appl. No.: 17/484,531

(22) Filed: Sep. 24, 2021

Related U.S. Application Data
(60) Provisional application No. 63/082,511, filed on Sep. 24, 2020.

(51) Int. Cl. G01T 1/04

(52) U.S. Cl. CPC G01T 1/04

(57) ABSTRACT

An alanine criticality accident dosimeter comprising at least two alanine pellets and at least two alanine pellets enhanced with moderator, and each pair of alanine pellet and enhanced alanine pellet is covered with a neutron filer or a photon filter. An improved method to determine radiation dose of a subject after an accident by measuring alanine pellets from a criticality accident dosimeter with neutron sensitivity, and improved discrimination between photon and neutron dose contributions.

### CROSS-REFERENCE TO RELATED APPLICATIONS

This application claims priority from U.S. provisional application No. 63/082,511, filed Sep. 24, 2020, the content of which is incorporated herein by reference.

### TECHNICAL FIELD

The invention relates to a criticality accident dosimeter that provides accurate and personal absorbed doses following an accident. More specifically, this invention relates generally to multi-element alanine dosimeter holder with filters.

### BACKGROUND

Personal dosimeter that is capable of providing timely information is critical for absorbed dose assessment and individual medical treatment following an accident. The Health Physics Society Standards Committee (HPSSC) notes in the current Dosimetry for Criticality Accidents Standard (ANSUHPS N13.3-2013), that “rapid and accurate assessment of personal absorbed doses resulting from a criticality accident may be of the utmost importance for exposed individuals and assisting with their medical treatment.”

Existing Nuclear Accident dosimetry (NAD) or Criticality Accident Dosimetry are based on the activity measurements of the activation products. Dose measurements often require the use of sensitive but expensive counting equipment. While gamma spectrometers are used for indium, copper and gold, and beta counters are used for sulfur. The necessary counting equipment is usually not easily transportable due to the significant weight of the shielding materials used, and delicacy of the counters.

The measuring process can be both time and labor intensive. For example, in order to measure neutron dose in a broad energy range, several different foils need be measured, some of them with a special cover (e.g. cadmium). These time and labor consuming measurements need to be carried out by specially trained and experienced personnel. The typical time required for such dose measurements is about an hour per dosimeter. Moreover the results obtained in terms of activity require a number of corrections, e.g. time since the accident, sample geometry in order to calculate absorbed dose.

Another significant limitation of existing accident dosimeters is that they need to be analyzed within a very short time following an accident. This is due to the short half-life of the activated products:

Sulfur pellets are sensitive to neutrons with energies greater than 3.0 MeV by the reaction: ³²S+n=³²P+β, ³²P→T_{1/2}=14.29 days, beta-emitter with E=1.17 MeV

Indium foils are sensitive to neutrons with energies greater than 1.0 MeV.

There are several activation products from thermal neutron activation of indium. Only the ^{115m}In has a half-life greater than a few seconds. The reaction is: ¹¹⁵In+n=^{115m}In+γ; T_{1/2}=0.188 days; gamma-emitter with E=0.336 MeV

Gold foil (bare and Cd-covered). The reaction is: ¹⁹⁷Au(n−γ)¹⁹⁸Au→T_{1/2}=2.697 days, beta-emitter with E=0.411 MeV

This means that existing criticality dosimeters can be analyzed only once (due to the time constraint), and they are completely useless if not analyzed during the first week following the occurrence of an accident.

Therefore, it is highly desirable to have an inexpensive NAD, which can be read several times during at least one year following an accident, and only requires simple, easily transportable, and inexpensive equipment to read.

Alanine dosimetry is an internationally approved technique for dose measurement in various radiation fields. Alanine produces radicals (unpaired electrons) upon irritation. The number of the radicals is proportional to the radiation dose absorbed over a wide dose range. Crystalline L-α-alanine is a well-known material for Electron Paramagnetic Resonance (EPR) dosimetry, which is used in radiation laboratories in both reference and transfer dosimetry (Regulla, 2005; Baffa and Kinoshita, 2014). Because it is inconvenient to utilize a powder as dosimeter, alanine pellets, made from L-α-alanine powder mixed a binder (such as 10-20% of paraffin), are used for dosimetry. Typical standard alanine pellets have a diameter of 4.5 mm, and a height of 3.5 mm. The ISO/ASTM 51607-2013, Standard Practice for Use of the Alanine-EPR Dosimetry System, provides official guidance for its use.

Alanine dosimeters have several advantages over other dosimeter products. They are small, compact and easy to handle and are characterized by low influence of temperature, humidity and dose rate. Alanine dosimeters also offer a wide measuring range from 2 Gy to 200 kGy, which makes them applicable for radiation therapy, blood components irradiation as well as industrial irradiation.

The L-α-alanine's superior dosimetry properties over other dosimeter products include:
Tissue equivalence for photons and electron irradiation;
Sensitivity to fast neutrons;
Linear dose response;
High stability of radiation-induced radicals (>1 year);
Non-destructive read-out procedure;
No sample treatment before EPR measurement;
Alanine pellets are commercially produced by several companies and very inexpensive (10-50 cent per pellets);
Fast and automatic dose readout (<3 min);
Onsite measurement of absorbed dose using transportable EPR spectrometers.

Despite the many advantages of Alanine dosimetry, its application is still limited by a few problems. Hayes et al., (2000) reported an accuracy of 10% for 100 mGy dose measured in alanine pellets in a blind intercomparison. Irradiated alanine dosimeters, which were stored, exhibited compound spectral EPR signal fading of ca 3% over 9 months. While the report is encouraging, the tests have to be carried out in a complex method, which utilize multiple techniques, such as polynomial filtration of the EPR spectrum, dosimeter rotation during scanning, subtraction of all non-radiogenic signals. The method also requires the use of an EPR standard, which is inserted into the resonator during measurement.

In 2008, Trompier et al., reported results of alanine dosimeters measurements of neutron doses in a criticality accident exercise at the CALIBAN irradiation facility. In this dosimetry study, photon contribution was measured by TLD in Al₂O₃ powder, which was subtracted from the total dose measured by EPR spectrometry in Alanine pellet. Table 1 demonstrates that alanine dosimeters were able to provide results for neutron dose measurements that is comparable to other dosimetric techniques.

TABLE 1
Comparison of tissue kerma (Gy) measured by the different techniques
normalized per 10¹⁶ fissions for neutrons and photons at the reference
point (d = 3 m, h = 1.2 m, 90° axis) (Trompier et al., 2008)

| Radiation | Technique | Tissue kerma |
|---|---|---|
| Neutron | Activation | 0.51 ± 0.13 |
| | Alanine | 0.58 ± 0.06 |
| | Silicon diodes | 0.60 ± 0.06 |
| Photon | TLD (Al₂O₃) | 0.11 ± 0.01 |

However, an additional independent dosimeter and processing equipment (TLD) must be used to measure photon dose before the accurate neutron readings can be produced. Furthermore, alanine dosimeters has relatively low sensitivity to neutrons, e.g. especially to thermal neutrons.

In order to increase its neutron sensitivity it was proposed to add 5% of Gd₂O₃ to the composition of alanine pellets. Gd₂O₃ doped alanine pellets were found to increase the EPR signal by a factor of 3.45 in case of PMMA phantom (Marrale et al., 2015). Having two types of alanine pellets with different sensitivity to neutrons gives an opportunity to build a new type of criticality dosimeters based on the same dosimetric material (alanine) and the same method of readout, e.g. EPR. However, because Gd₂O₃ doped alanine pellets is not commercially available, its application as NAD is significantly limited.

### DETAILED DESCRIPTION OF THE FIGURES

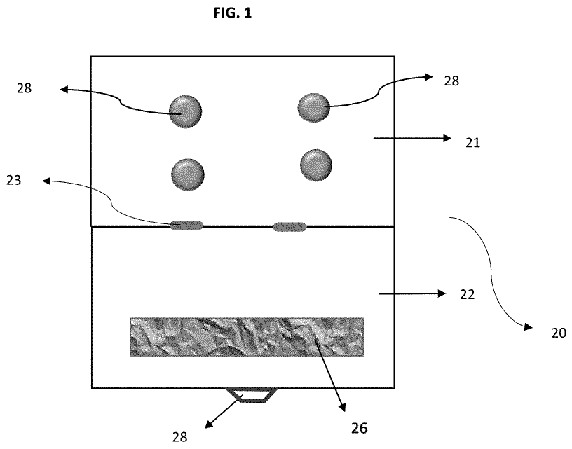

FIG. 1 Diagram of the alanine dosimeter holder.

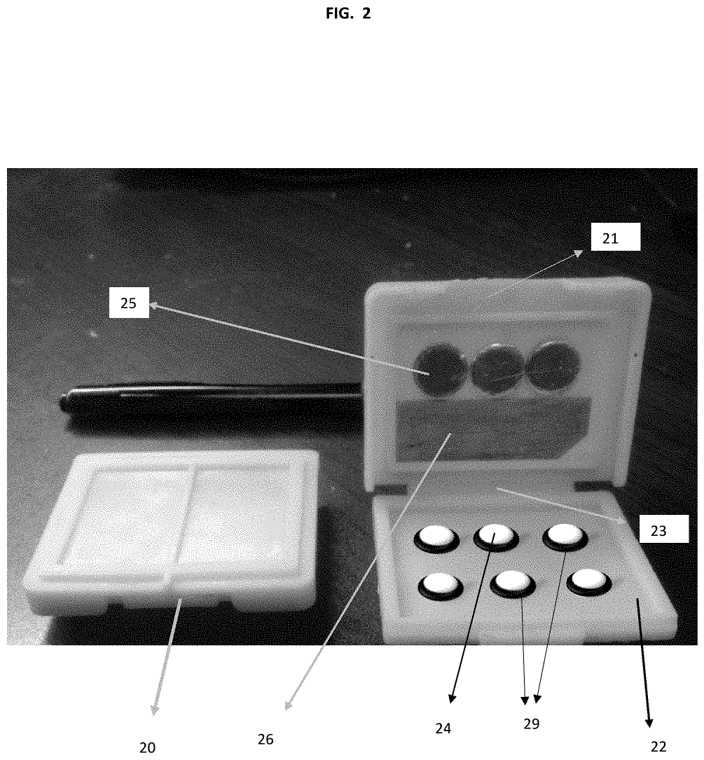

FIG. 2 Photo of the alanine dosimeter holder prototype.

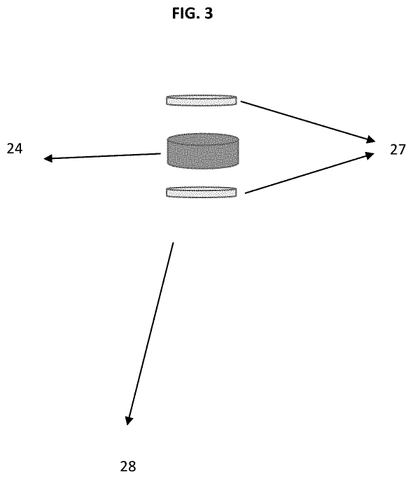

FIG. 3 Enhanced Alanine pellet made with alanine pellet and ⁶LiF chip/pellet.

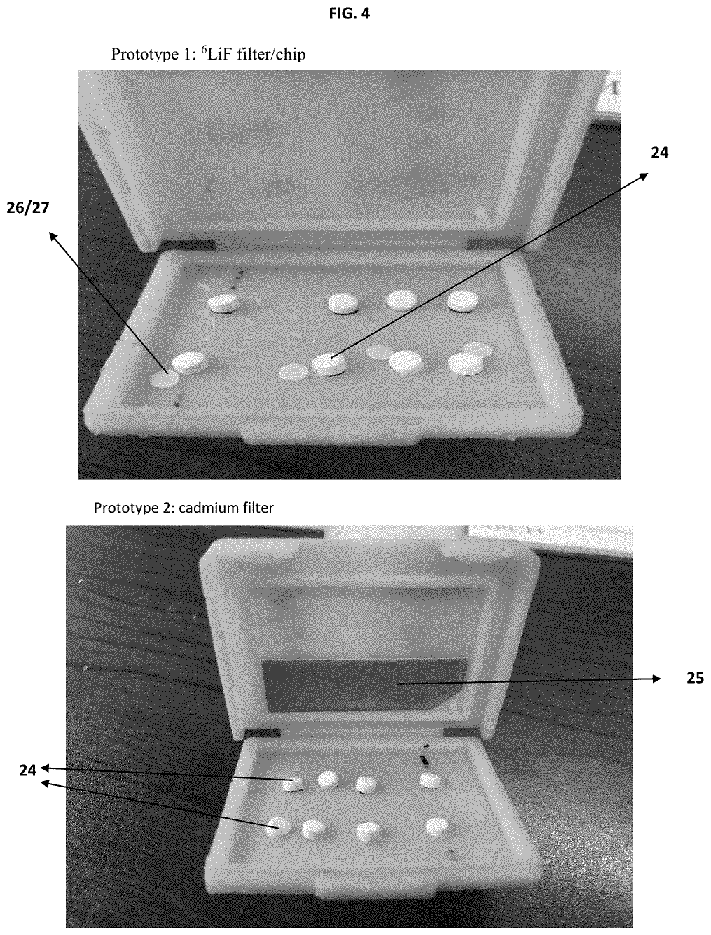

FIG. 4 Two prototype dosimeter holder designs.

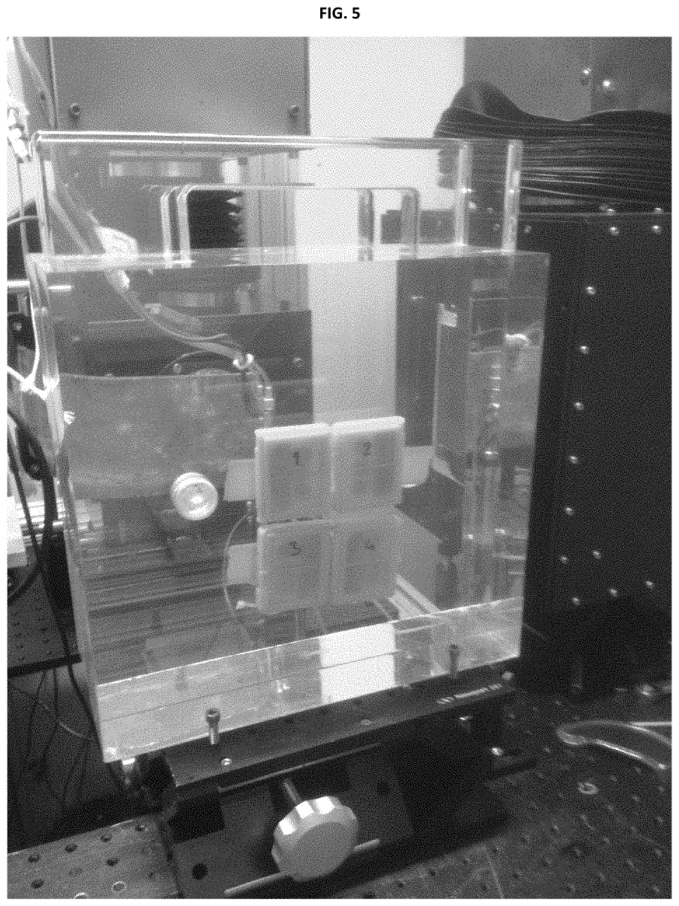

FIG. 5 shows Neutron irradiation setup: prototype holders are placed on the PMMA slab phantom.

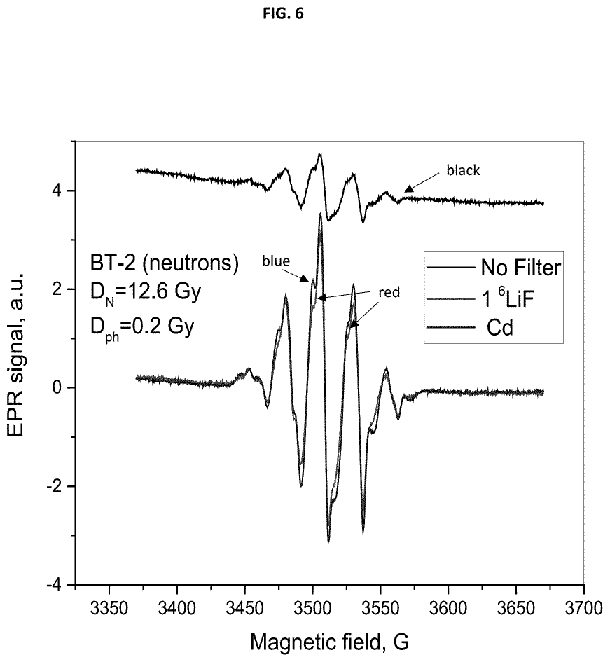

FIG. 6 Comparison of EPR signals from neutron-irradiated bare alanine (black line on top), alanine pellets irradiated behind ⁶LiF single pellet (red line) and alanine pellets irradiated behind cadmium plate (blue line).

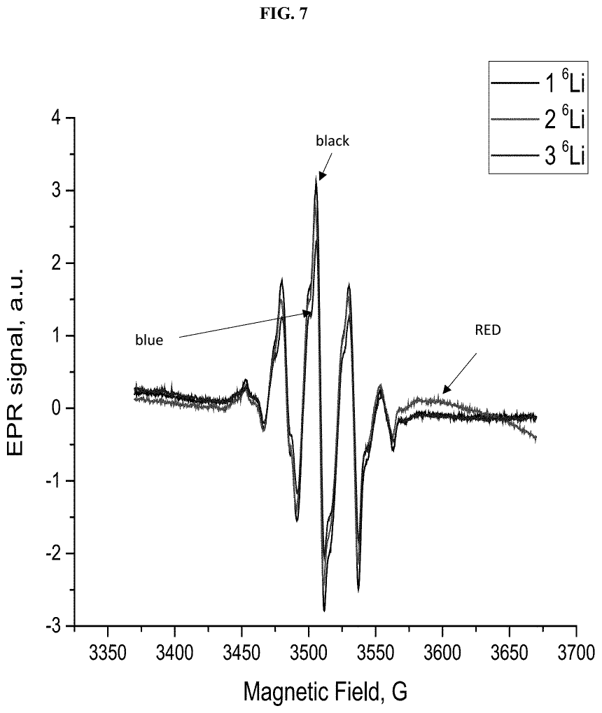

FIG. 7 EPR signals of neutron-irradiated alanine pellets behind ⁶LiF filters with different thicknesses.

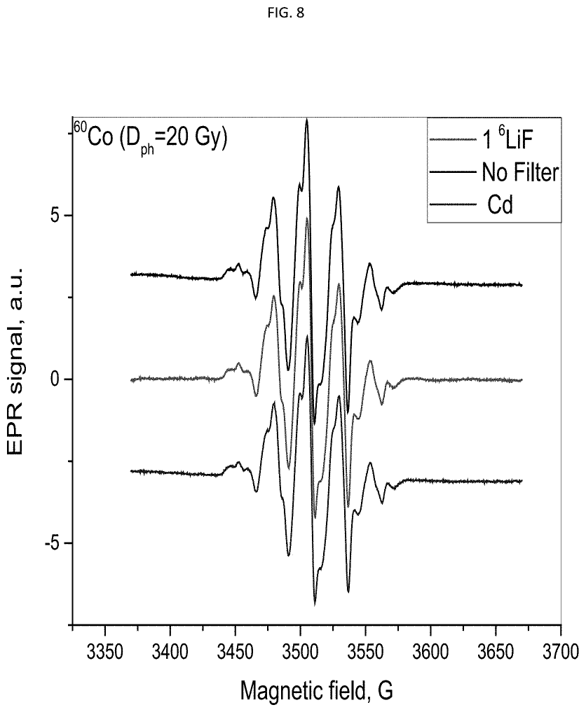

FIG. 8 EPR signals of gamma-irradiated alanine pellets behind ⁶LiF and cadmium filters (top to bottom: no filter, 1⁶LiF filter and cadmium filter).

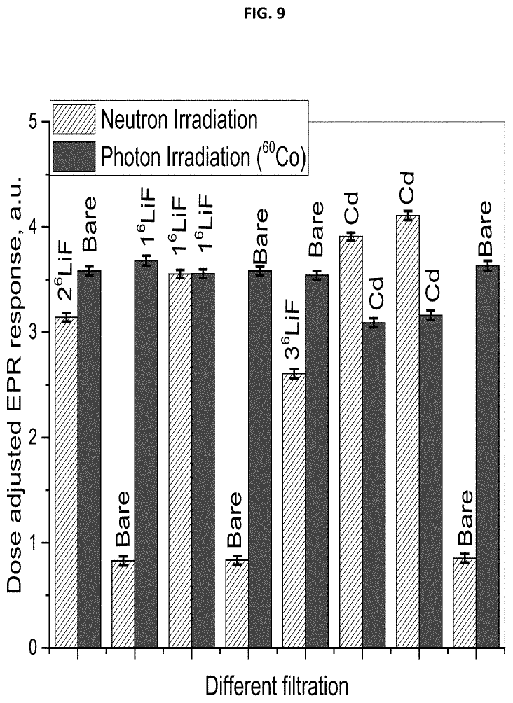

FIG. 9 Comparison of the EPR response from alanine pellets behind different filters during irradiation with BT-2 (neutron) and ⁶⁰Co (gamma). The EPR responses are normalized to the same nominal dose of 10 Gy.

### DETAILED DESCRIPTIONS OF THE INVENTION

The present invention aims to improve criticality accident dosimetry. The criticality accident dosimeter of present invention provides better neutron sensitivity, and is capable of discriminate photon and neutron dose contributions without requiring special Gd₂O₃ doped alanine pellets or additional photon dosimeter.

Instead of using two types of alanine pellets with different composition (e.g. with and without Gd₂O₃), this invention proposes a new design of criticality accident dosimeter based on the same dosimetric material (alanine) and the same method of readout, e.g. EPR. In order to enhance the photon-neutron differentiation of alanine, filters made of material that is capable of improving alanine's neutron sensitivity are placed in front of standard alanine pellets.

It is well known that some materials, such as cadmium and ⁶Li, can convert neutrons into other types of particles to which alanine has higher sensitivity. A number of materials exist with high neutron-capture cross sections. The capture of neutron then directly or indirectly provides particles that subsequently produce radiation-induced radicals in alanine. A partial list of these types of nuclear reactions is given below:

n+⁶Li→α+³H (1)

n+¹¹³Cd→¹¹⁴Cd*→¹¹⁴Cd+γ (2)

n+¹⁵⁷Gd→¹⁵⁸Cd*→¹⁵⁸Cd+γ (3)

In case of a ⁶Li filter, the neutron irradiation will generate a particles and tritium ions as a result of the reaction (1), which will produce radiation-induced radicals in alanine pellets placed behind the filter. In case of a cadmium filter, neutrons will produce a photon component (see nuclear reactions (2) and (3)) contributing to the dose measured by the alanine pellet behind the cadimium filter. Although reactions (1-3) are well known in the field. No one has applied these reactions in NAD design. Without building a prototype, and experimentally measuring the effect of the neutron sensitivity enhancement, it was unclear if this dosimetry design is feasible or sensitive enough for NAD application.

### Holder Design

A criticality accident dosimeter of the present invention, comprises at least four alanine pellets, of which at least two of the alanine dosimeter pellets are placed behind a filter; wherein said filter enhances the sensitivities of said alanine dosimeter pellets covered by the filter. The filter may be made of ⁶Li or cadmium. The personal criticality dosimeter of the present invention upon exposure to ionizing radiation, can produces radicals that remain stable for at least a year.

In one embodiment, a personal criticality accident dosimeter of present invention for ascertaining radiation dosage comprising: at least four alanine dosimeter pellets, and a dosimeter holder, which comprises a plurality of supports, each designed to hold one said alanine dosimeter pellet and a ⁶Li filter or a cadmium filter, wherein said ⁶Li filter or a cadmium filter covers at least two of said alanine pellets.

Referring to FIG. 1 and FIG. 2, a dosimeter holder 20 of the present invention, comprises a front cover 21 and a back cover 22, which are joined by hinges 23 or other fasteners so that the dosimeter holder 20 may be opened or closed as desired. A fastener, such as a clip, a clasp or a hasp 28, for securing the dosimeter to a person's clothing, is also provided on the outer rim of the holder 20. The body of the holder 20 can be made from Plexiglas to support tissue equivalency of alanine. The inside surface of said back cover 22 comprises at least four of mounting supports 29, each adapted to hold and affix one alanine pellet 24. One or more filters 25 or 26 are affixed to the inside surface of said front cover 21, wherein said filter 25/26 is adapted to be placed in front of at least two of the alanine pellets when the front cover and back cover of the holder is closed. The addition of ⁶LiF (TLD-600H) 26 filter or a cadmium filter 25 to the alanine dosimeter pellets 24 enhances the sensitivities of said alanine dosimeter pellet. The other filters with similar properties to discriminate photon exposure against neutron exposure can also be used.

In another embodiment, a personal criticality accident dosimeter of present invention for ascertaining radiation dosage comprises: at least two standard alanine dosimeter pellets 24, and at least two enhanced alanine dosimeter pellets 28, wherein said enhanced dosimeter pellets is made by adding one or more filter chip/pellets 27 to an alanine dosimeter pellet as shown in FIG. 3 or FIG. 4. As shown in FIG. 3, an enhanced alanine pellet 28 is made by sandwich an alanine dosimeter pellet 24 between two ⁶Li filter chips or gadolinium filter chips 27. Dosimetric chip/pellet 27 made of ⁶LiF: Mg,Cu,P (TLD-600H™, THERMO SCIENTIFIC™, Waltham, Mass.) or cadmium can be used for this purpose. These dosimetric chips/pellets are commercially available, and typically have a diameter of 4 mm, which is exactly equal to the diameter of a standard alanine pellet.

### Example 1: Prototype Dosimeter Holders

Two types of dosimeter holder have been designed and built (as shown in FIG. 4).

Type 1 dosimeter holder is designed to hold four standard alanine pellets (size 4×2.4 mm, AERIAL®, Illkirch—France) without any filtration and another four standard alanine pellets placed behind a ⁶LiF filter when the holder is closed. Standard ⁶LiF pellets (size 3.6×0.015 mm) were used as ⁶LiF filter. These ⁶LiF pellets were purchased from Thermo Eberline LLC (Franklin, Mass.). In order to check the effect of ⁶LiF filter thickness on sensitivities of dosimeter, ⁶LiF filter thickness (e.g. three, two and one ⁶LiF chips) are ted.

Type 2 dosimeter holder is designed to hold four alanine pellets without any filtration and another four alanine pellets behind a cadmium filter (44×15×0.5 mm).

### Example 2: Irradiation Testing

### Irradiation Set up:

Neutron Irradiation: 20 MW research reactor of the National Institute of Standards and Technology (NIST) was utilized for the testing of the prototype holders. The reactor is D₂O cooled and moderated. The core is comprised of thirty enriched-uranium fuel elements of a unique, split-core design. It utilizes low-energy neutrons, which are often described as thermal and cold. Reactor neutron imaging station BT2 was used for the holders' irradiation. The irradiation was done on the standard ANSI PMMA phantom (as shown in FIG. 5). Four holders with alanine dosimeters were irradiated simultaneously. BT-2 neutron flux and energy spectrum can be changed using different combinations of apertures and beams (see Appendix A). Flux 1.38E+07 n/(cm2 sec) was used for irradiation. Neutron dose rates were calculated by Monte Carlo N-Particle Transport Code (MCNP) separately for fast and slow neutrons using 1 eV as the cutoff. According to MCNP 1.38E+07 n/(cm2 sec) flux has about 20% of thermal neutrons (<1 eV). Calculated neutron dose rates (Table 2) were used for comparison of alanine response in the designed holders to the neutron irradiation response of bare alanine to ⁶⁰Co. Dosimeter prototypes with various ⁶LiF moderator thickness (three, two and one ⁶LiF discs) are irradiated at high dose. Compare the intensity and shapes of the resulting signals. Determine the best moderator to enhance its neutron sensitivity.

TABLE 2
MCNP calculated dose rates used for testing.

| Type of exposure | Dose rate, mrem/s |
|---|---|
| Fast neutron | 62.639 |
| Thermal neutron | 14.082 |
| Gamma | 0.5694 |

Gamma Irradiation: an AFRRI Co60 source was utilized for the testing of the prototype holders with similar set up.

### EPR Measurements

A Bruker ELEXSYS 500 (Bruker BioSpin, Billerica, Mass.) spectrometer equipped with a super-high-Q resonator ER 4123 SHQE in the X-band (9-10 GHz) was used for the measurements. All four pellets irradiated under the same conditions were put together into a sample tube and measured. Table 3 shows the recorded settings. The EPR measurement (dose evaluation) takes only 3.5 minutes (Table 3). For statistical purposes, the measurement of each sample was performed for five times.

TABLE 3
EPR recording conditions - Spectrometer settings

| Parameter | Value | |
|---|---|---|
| HF modulation | 100 | kHz |
| Amplitude of HF modulation | 3 | G |
| Microwave power | 2 | mW |
| Receiver gain | 20000 | |
| Time constant | 1.28 | ms |
| Converse time | 5.12 | ms |
| Number of points | 1024 | |
| Sweep time | 5.243 | s |
| Number of scans | 40 | |
| Total recording time | 3.5 | min |
| Central field | 3480 | G |
| Sweep field | 50 | G |

### Dose Algorithm

According to Trompier et al., 2008 the total EPR radiation response of alanine at mixed neutron-photon irradiation in terms of its sensitivity to ⁶⁰Co gamma rays, R can be generally described by the following formula:

R=kDₙ+hD_{γ} (1)

Where k is the sensitivity of alanine to neutrons relative to ⁶⁰Co gamma rays, h is alanine sensitivity to the photons relative to ⁶⁰Co gamma rays. Both sensitivities are measured in terms of the EPR radiation response per dose unit. Dₙ and D_{γ} are the neutron and photon absorbed doses in tissue. In case of alanine use without different filtration, it is impossible to determine photon and neutron doses separately. Therefore 2008 Trompier et al. 2008 additionally used thermoluminescent dosimetry (Al₂O₃) to measure photon dose alone. If there is a holder with alanine pellets behind different filters then Eq. (1) can be written for each filtration separately and neutron and photon doses can be determined without the use of additional dosimeters, e.g. TLD. In case of holder prototype using a cadmium filter the system of two equations can be written in the following way:

$$\begin{matrix}{R}_{Cd} = {k}_{Cd} {D}_{n} + {h}_{Cd} {D}_{γ} & ( 3 ) \\ {R}_{bare} = {k}_{bare} {D}_{n} + {h}_{bare} {D}_{γ} \\ or & ( 4 ) \\ {D}_{n} = \frac{{R}_{Cd} - {h}_{Cd} {D}_{γ}}{{k}_{Cd}} & ( 5 ) \\ {D}_{γ} = \frac{{R}_{bare} - {k}_{bare} {D}_{n}}{{h}_{bare}} & ( 6 )\end{matrix}$$

D_{γ} in the first equation can be substituted by the second equitation:

$${D}_{n} = \frac{{R}_{Cd}}{{k}_{Cd}} - \frac{{h}_{Cd}}{{k}_{Cd}} ( \frac{{R}_{bare} - {k}_{bare} {D}_{n}}{{h}_{bare}} ) \qquad ( 7 )$$

This equation can be solved relatively to Dₙ:

$$\begin{matrix}{D}_{n} = \frac{{R}_{Cd} {h}_{bare} - {h}_{Cd} {R}_{bare}}{{k}_{Cd} {h}_{bare} - {h}_{Cd} {k}_{bare}} & ( 8 ) \\ {D}_{γ} = \frac{{R}_{bare} {k}_{Cd} - {h}_{bare} {R}_{Cd}}{{k}_{Cd} {h}_{bare} - {h}_{Cd} {h}_{bare}} & ( 9 )\end{matrix}$$

Eqs. (8) and (9) allow to calculate neutron and gamma absorbed doses if the proposed prototype with a cadmium filter was used. Data (k, h, and R) from Tables 3 and 4 allow to verify the correctness of the proposed equations i.e. that the calculated neutron and photon doses are equal to the actually delivered neutron and photon doses.

In the case of the prototype with a ⁶LiF filter similar equations (with the change of Cd to Li) can be proposed for neutron and gamma dose calculations, as follows:

$$\begin{matrix}{D}_{n} = \frac{{R}_{Li} {h}_{bare} - {h}_{Li} {R}_{bare}}{{k}_{Li} {h}_{bare} - {h}_{Li} {k}_{bare}} & ( 10 ) \\ {D}_{γ} = \frac{{R}_{bare} {k}_{Li} - {h}_{bare} {R}_{Li}}{{k}_{Li} {h}_{bare} - {h}_{Li} {h}_{bare}} & ( 11 )\end{matrix}$$

### Results of Porotype Dosimeter Holders' Testing

FIG. 6 shows EPR signals of the simultaneously irradiated (with the same dose) bare alanine (black line on top), alanine pellets irradiated behind a ⁶LiF single pellet (red line) and alanine pellets irradiated behind a cadmium plate (blue line). It is obvious that both proposed filters (⁶LiF and Cd) result in a significant increase of alanine sensitivity to neutron exposure. FIG. 7 shows the effect of the thickness of the ⁶LiF filter on the EPR spectrum of alanine irradiated with neutrons. One can see that the effect of the sensitivity enhancement is reduced with ⁶LiF thickness increases. This is probably due to the higher absorption of the generated α-particles inside thicker filters. Filter with one ⁶LiF chip offers the best sensitivity enhancement.

The simulated neutron flux spectrum, neutron dose rate spectrum, core gamma flux spectrum, and core gamma dose rate spectrum (with the cooled 10 cm bismuth filter in the beam) are shown in FIG. 7, FIG. 8, and FIG. 9 respectively. The lower figures show the corresponding cumulative distribution functions for which the high energy limits give the energy-integrated quantities. The neutron and core gamma dose rate curves in FIG. 9 were obtained from modified flux tallies in which NCRP dose rate factors extrapolated to each energy bin center were applied. Table 4 provides absolute numbers of the neutron sensitivity increase for different filters tested. One can see from Table 4 that the cadmium filter provides almost a factor of five neutron sensitivity increase, and the ⁶LiF effect is only slightly less. It is important to note that this effect for both filters tested is more significant than from doping alanine with Gd₂O₃, proposed by Marrale et al., 2015. Table 5 shows the result of the ⁶⁰Co irradiation

TABLE 4
Summary of the BT-2 irradiation. The contribution of the photon
irradiation to alanine response was considered equal to 0 at k calculations.
In reality, its contribution to the total (neutron + photon) dose was 1.6%.

| | Slow | Fast | Total | Photon | EPR | | |
|---|---|---|---|---|---|---|---|
| | neutron | neutron | neutron | Dose, | Response, | | |
| Filtration | dose, Gy | dose, Gy | dose, Gy | Gy | a.u. | k | |
| Double ⁶LiF | 1.487 | 11.113 | 12.600 | 0.205 | 3.96 ± 0.03 | 0.31 | k_{2Li} |
| No | 1.487 | 11.113 | 12.600 | 0.205 | 1.04 ± 0.01 | 0.08 | k_{bare} |
| Single ⁶LiF | 1.487 | 11.113 | 12.600 | 0.205 | 4.48 ± 0.03 | 0.36 | k_{Li} |
| No | 1.487 | 11.113 | 12.600 | 0.205 | 1.05 ± 0.03 | 0.08 | k_{bare} |
| Triple ⁶LiF | 1.487 | 11.113 | 12.600 | 0.205 | 3.28 ± 0.05 | 0.26 | k_{2Li} |
| Cadmium | 1.487 | 11.113 | 12.600 | 0.205 | 4.93 ± 0.02 | 0.39 | k_{Cd} |
| Cadmium | 1.487 | 11.113 | 12.600 | 0.205 | 5.18 ± 0.02 | 0.41 | k_{Cd} |
| No | 1.487 | 11.113 | 12.600 | 0.205 | 1.07 ± 0.01 | 0.09 | k_{bare} |

TABLE 5
Summary of the ⁶⁰Co irradiation

| | Photon | | | |
|---|---|---|---|---|
| Filtration | Dose, Gy | EPR Response, a.u. | h, a.u./Gy | |
| Double ⁶LiF | 20 | 7.16 ± 0.08 | 0.36 | h_{2Li} |
| No | 20 | 7.36 ± 0.05 | 0.37 | h_{bare} |
| Single ⁶LiF | 20 | 7.11 ± 0.04 | 0.36 | h_{Li} |
| No | 20 | 7.16 ± 0.02 | 0.36 | h_{bare} |
| No | 20 | 7.28 ± 0.06 | 0.35 | h_{bare} |
| Cadmium | 20 | 6.18 ± 0.03 | 0.31 | h_{Cd} |
| Cadmium | 20 | 6.22 ± 0.03 | 0.31 | h_{Cd} |
| No | 20 | 7.26 ± 0.03 | 0.36 | h_{bare} |

Thus neutron and photon doses for any photon-neutron mixture can be calculated by measuring the EPR response of alanine pellets irradiated in the proposed holders and using the determined parameters h and k.

### Conclusions

The experiments on prototype dosimeter holders demonstrated that the proposed cadmium and ⁶LiF filters (convertors) increase the sensitivity of alanine to neutron irradiation by almost a factor of five. The latter makes alanine even more sensitive to neutrons than to photons. Normally its sensitivity to neutrons is significantly lower than to photons.

### Example 3: Method of Using Inventive NAD to Determine Radiation Dose

Proposed and tested holder designs in combination with the developed dose algorithm allow to measure neutron and photon doses separately using only EPR measurements in alanine. This makes the entire dose measurement process fast (<10 min) and requiring only one type of dose readout equipment (EPR).

A method for determining the radiation dose by Electron Paramagnetic Resonance (EPR) dosimetry using alanine criticality accident dosimeter, comprises of 1) providing a subject with a criticality accident dosimeter holder containing at least two alanine pellets and at least two alanine pellets covered by a cadmium filter or a ⁶Li filter; 2) measuring the EPR spectrum of alanine pellets contained in said holder after a radiation exposure; and c) determining neutron and photon radiation doses using EPR measurements from step 2; c) calculating radiation dose exposed to said subject.

### REFERENCES

American National Standard ANSl/HPS N13.3-2013. Dosimetry for Criticality Accidents. American National Standards Institute, Inc. Health Physics Society, Mclean, Va.
Baffa, O., Kinoshita, A., 2014. Clinical applications of alanine/electron spin resonance dosimetry. Radiat. Environ. Biophys., 1-8.
Hayes R. B., Haskell E. H, Wieser A., Romanyukha A. A., Hardy B. L. and Barrus J. K. 2000. Assessment of an alanine EPR dosimetry technique with enhanced precision and accuracy. Nuclear Instruments & Methods in Physics Research A, 440, 453-461.
Regulla, D. F., 2005. ESR spectrometry: a future-oriented tool for dosimetry and dating. Appl. Radiat. lsot. 62, 117-127.
ISO/ASTM 51607-2013, Standard Practice for Use of the Alanine-EPR Dosimetry System, ASTM International, West Conshohocken, Pa., 2012, www.astm.org
Marrale M., Schmitz T., Gallo S., Hampel G., Longo A., Panzeca S., Tranchina L. 2015. Comparison of EPR response of alanine and Gd₂O₃-alanine dosimeters exposed to TRIGA Mainz reactor. Appl. Radiat. Isotop. 106, 116-120
Trompier, F., Huet, C., Medioni, R., Robbes, I., Asselineau, B., 2008. Dosimetry of the mixed field irradiation facility CALIBAN. Radiat. Meas. 43 (2), 1077-1080.

What is claimed is:

1) A criticality accident dosimeter for ascertaining radiation dosage comprising
a) at least four alanine dosimeter pellets; and
b) a dosimeter holder, which comprises
(i) a front cover and a back cover joined by one or more fasteners;
(ii) a plurality of supports on said back cover, wherein each support is adapted to hold one said alanine pellet; and
(iii) one or more filter affixed on said front cover, wherein each of said filter is adapted to cover at least two of said alanine pellets when the front and back cover of said holder is closed, whereas said filter enhances sensitivity of said alanine pellet.

2) The criticality accident dosimeter claim 1, wherein said alanine pellet comprising alanine and a binder.

3) The criticality accident dosimeter of claim 2, wherein the alanine is in crystalline form.

4) The criticality accident dosimeter of claim 1, wherein the filter is a cadmium filter or ⁶Li filter.

5) The criticality accident dosimeter of claim 4, wherein said cadmium filter is a cadmium dosimetric pellet/chip.

6) The criticality accident dosimeter of claim 4, wherein said ⁶Li filter is a ⁶Li dosimetric pellet/chip.

7) A method for determining the radiation dose by Electron Paramagnetic Resonance (EPR) dosimetry using alanine criticality accident dosimeter, comprising
a) providing a subject with a criticality accident dosimeter holder containing at least two alanine pellets and at least two alanine pellets covered by a cadmium filter or ⁶Li filter;
b) measuring the EPR spectrum of alanine pellets contained in said holder after a radiation exposure; and
c) determining radiation dose of said alanine pellet with the cadmium filter or ⁶Li filter and radiation dose of said alanine pellet without the cadmium filter or ⁶Li filter using measurements from step b).
c) calculating radiation dose exposed to said subject.
